(19) United States
(12) Patent Application Publication
(10) Pub. No.: US 2014/0247242 A1
(43) Pub. Date: Sep. 4, 2014

(54) TOUCH SCREEN PANEL

(71) Applicant: DONGBU HITEK CO., LTD., Seoul (KR)

(72) Inventors: Jin Ah LEE, Incheon (KR); Hyun SONG, Suwon-si (KR); Young Wook KIM, Seoul (KR); Won Cheol HONG, Seoul (KR); Joon SONG, Seoul (KR); Ae Young MA, Gunsan-si (KR); Jon Ghwan KO, Gwangmyeong-si (KR); Han Kyung KIM, Bucheon-si (KR)

(73) Assignee: DONGBU HITEK CO., LTD., Seoul (KR)

(21) Appl. No.: 13/803,550

(22) Filed: Mar. 14, 2013

(30) Foreign Application Priority Data
Mar. 4, 2013 (KR) 10-2013-0023048

(51) Int. Cl. H05K 3/00; G06F 3/044

(52) U.S. Cl. CPC H05K 3/0011; G06F 3/044
USPC 345/174; 29/622

(57) ABSTRACT

A touch screen panel and a method of manufacturing the same are provided. A touch screen panel can include a substrate, driving lines on the substrate, sensing patterns on the substrate, and a dielectric on the substrate and the driving lines. Sensing lines can be disposed on the dielectric and arranged in a perpendicular direction to the driving lines. The sensing lines can be electrically connected to the sensing patterns.

### CROSS-REFERENCE TO RELATED APPLICATION

This application claims the benefit under 35 U.S.C. §119 of Korean Patent Application No. 10-2013-0023048, filed Mar. 4, 2013, which is hereby incorporated by reference in its entirety.

### BACKGROUND

In the related art, a capacitive touch screen panel display is manufactured in various types, including a glass/film/film (GFF) type, in which an indium tin oxide (ITO) film with an X-axis touch sensor pattern thereon and an ITO film with a Y-axis touch sensor pattern thereon can be stacked on a window glass. Another type of capacitive touch screen panel display is a glass/glass (GG) type having an X-axis touch sensor pattern and a Y-axis touch sensor pattern on a top surface and a bottom surface thereof.

FIG. 1 is a cross-sectional view of a related art touch screen panel display. Referring to FIG. 1, a touch screen panel display 10 of a GFF type includes a display 11, an X-axis ITO film 13 stacked on the display 11, a Y-axis ITO film 15 stacked on the X-axis ITO film 13, and a window glass 17 stacked on the Y-axis ITO film 15. In addition, optical clear adhesives (OCAs) 12, 14, and 16 are formed between the display 11 and the X-axis ITO film 13, the X-axis ITO film 13 and the Y-axis ITO film 15, and the Y-axis ITO film 15 and the window glass 17. An X-axis touch sensor pattern 13a is formed on a top surface of the X-axis ITO film 13, and a Y-axis touch sensor pattern 15a is formed on a top surface of the Y-axis ITO film 15.

GG type touch screen panels, in which a metal pattern is more easily formed on an ITO film compared to the touch screen panel having the above described structure, are also used.

These various kinds of the related art structures have a structure where a pattern (electrode) arranged in an X-axis, and a pattern (electrode) arranged in a Y-axis are stacked. These electrodes are connected to a circuit element such as a flexible printed circuit board (FPCB), and touch positions thereof are detected by the circuit element, such as the FPCB.

However, since the electrodes are arranged to intersect each other in an X-axis and a Y-axis, and stacked up and down, a wire connecting the circuit element such as the FPCB and the electrodes bend. The bent wire may cause disconnection, and subsequently cause defects of a touch screen panel.

That is, since a wire connected to an X-axis electrode and a wire connected to a Y-axis electrode are not in the same plane, there may be a wire disposed at a different position than a circuit device such as a FPCB.

### BRIEF SUMMARY

Embodiments of the subject invention provide a touch panel screen, and methods for fabricating and using the same, for inhibiting a step from occurring in wires connected to electrodes which are arranged in a matrix type in order to detect a touch by a user.

In an embodiment, a touch screen panel includes: a substrate; a plurality of driving lines on the substrate; a plurality of sensing patterns on the substrate; a dielectric formed on the substrate and the driving lines; a plurality of sensing lines on the dielectric and arranged in a perpendicular direction to the driving lines; and a plurality of trace lines. Each driving line of the plurality of driving lines can be electrically connected to (e.g., in direct physical contact with) a trace line, and each sensing line of the plurality of sensing lines can be electrically connected to (e.g., in direct physical contact with) a trace line. Also, each sensing line can be electrically connected to (e.g., in direct physical contact with) a sensing pattern of the plurality of sensing patterns.

In another embodiment, a method of manufacturing a touch screen, the method comprising: forming a thin film on a substrate; forming a plurality of sensing patterns and a plurality of driving lines by patterning the thin film; forming a dielectric over the driving lines and the substrate; and forming a plurality of sensing lines on the dielectric and arranged in a perpendicular direction to the driving lines. Each sensing line can be electrically connected to (e.g., in direct physical contact with) a sensing pattern of the plurality of sensing patterns.

### BRIEF DESCRIPTION OF THE DRAWINGS

FIG. 1 is a cross-sectional view of a related art touch screen panel display.

FIG. 2 is a plan view of a touch screen panel according to an embodiment of the subject invention.

FIG. 3 is a cross-sectional view taken along line A-B in FIG. 2.

FIGS. 4 to 8 are cross-sectional views of a method of manufacturing a touch screen panel according to an embodiment of the subject invention.

### DETAILED DESCRIPTION

Reference will now be made in detail to the embodiments of the present disclosure, examples of which are illustrated in the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

In addition, the terms “first” and “second” can be selectively or interchangeably used for the members. In the figures, a dimension of each of elements may be exaggerated for clarity of illustration, and the dimension of each of the elements may be different from an actual dimension of each of the elements. Not all elements illustrated in the drawings must be included.

A touch panel screen display according to embodiments of the subject invention will be described in detail with reference to the accompanying drawings. The invention may, however, be embodied in many different forms and should not be construed as being limited to the embodiments set forth herein.

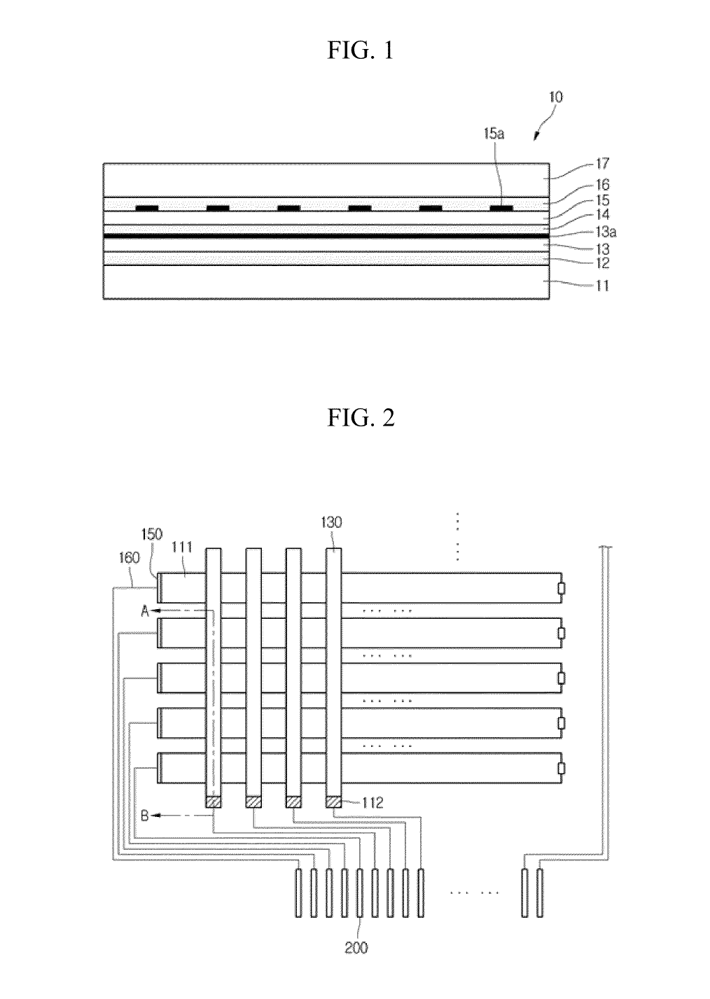

FIG. 2 is a plan view of a touch screen panel according to an embodiment of the subject invention.

Referring to FIG. 2, a touch screen panel can include driving lines 111 and sensing lines 130, arranged in a grid or a matrix type in order to detect a touch by a user.

Contacts 150 can be formed at end portions of the driving lines 111 (e.g., at end portions of a common side of the driving lines 111), and each of the driving lines 111 can be connected to a trace line 160 through the contacts 150. For example, each driving line 111 can be connected to a single trace line 160, respectively, through a contact 150, respectively. Each of the trace lines 160 can be connected (e.g.; in direct, physical contact with; electrically connected to) to any one of multiple ports 200, and a circuit element, such as a flexible printed circuit board (FPCB), connected to the ports 200 (e.g.; in direct, physical contact with; electrically connected to) can measure capacitance transferred from the driving lines 111. Though a FPCB is shown for exemplary purposes, embodiments are not limited thereto. The circuit elements can be any suitable circuit element.

When the driving lines 111 are arranged in an X-axis, the sensing lines 130 are arranged in a Y-axis. Though this arrangement is shown for exemplary purposes, embodiments are not limited thereto. For example, the driving lines 111 can be arranged in a Y-axis, and the sensing lines 130 can be arranged in an X-axis

The sensing lines 130 can be respectively connected to sensing patterns 112, such that each sensing line 130 is connected to one sensing pattern 112. The sensing lines 130 can be in direct, physical contact with the sensing patterns 112 The sensing patterns 112 can be connected to the ports 200 through the trace lines 160. For example, each sensing pattern 112 can be connected to a single trace line 160, which can then be connected to a single port 200. The sensing patterns 112 can be in direct, physical contact with the trace lines 160.

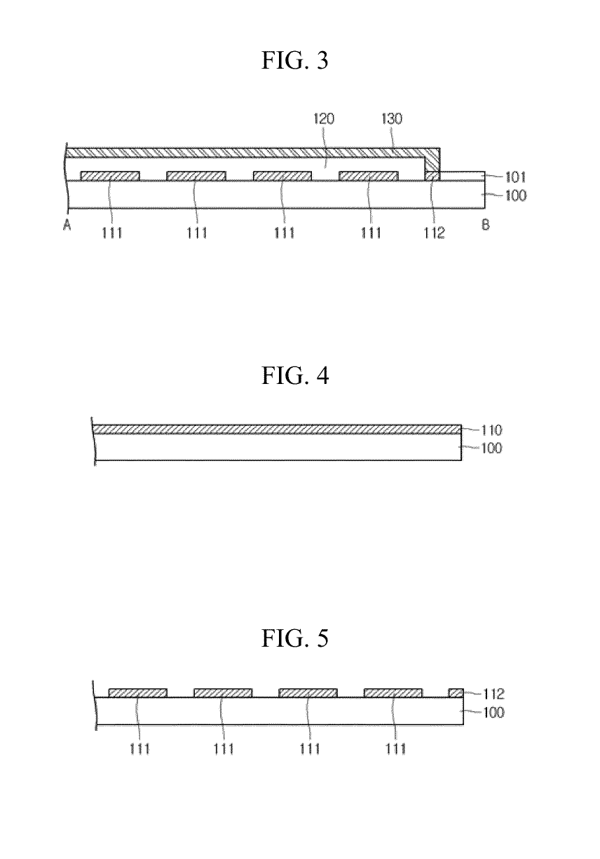

FIG. 3 is a cross-sectional view taken along line A-B in FIG. 2.

An electrode material can be coated on a substrate 100. The electrode material can be, for example, indium tin oxide (ITO), though embodiments are not limited thereto. The substrate 100 can be, for example, a glass substrate, though embodiments are not limited thereto. The multiple driving lines 111 and the multiple sensing patterns 112 can be formed by patterning the electrode material (e.g., ITO).

Interconnections 101 can be formed on the substrate connected to the sensing lines 130. The interconnections can be formed of, for example, a metal or ITO, though embodiments are not limited thereto. The interconnections 101 can be formed together with the patterning of the electrode material (e.g., ITO), when the electrode material (e.g., ITO) is patterned to form the driving lines 111 and the sensing patterns 112, or coated in advance (e.g., with a metal) on the substrate 100. In an embodiment, the interconnections 101 can be connected to the sensing lines 130 and can be formed in advance on the substrate 100 by patterning coated ITO, or using a conductive material such as ITO or a metal.

The driving lines 111 and the sensing patterns 112 can be formed of the same material. The material can be, for example, ITO, though embodiments are not limited thereto. The thicknesses of the driving lines 111 can be the same or approximately the same as those of the sensing patterns 112. For example, the thickness of each driving line 111 can be the same as that of all other driving lines 111, the thickness of each sensing pattern 112 can be the same as that of all other sensing patterns 112, and the thickness of each driving line 111 can be the same as that of all sensing patterns 112.

In an embodiment, a dielectric 120 can be formed on a substrate 100 including the driving lines 111. In a particular embodiment, the dielectric can be formed on the driving lines 111 but not formed on the sensing patterns 112.

The sensing lines 130 can be formed on the dielectric 120 and the sensing pattern 112. Insulation between the sensing lines 130 and the driving lines 111 can be achieved by the dielectric 120. The sensing lines 130 can have an ITO thin film deposited thereon.

Positions where the driving lines 111 are respectively connected to the trace lines 160, and positions where the sensing lines 130 are respectively connected to the trace lines 160 can be the same. That is, since a portion of the sensing lines 130 can be formed on side walls of the dielectric 120, and the sensing lines 130 can be connected to the sensing patterns 112 formed on the substrate 100, an electric signal can be transferred through the sensing patterns 112.

Although not shown in FIG. 3, the trace lines 160, the driving lines 111 and the sensing patterns 112, patterned on the substrate 100, can be formed at the same height from the substrate 100. This means that they may be connected by wires to the circuit element (e.g., a FPCB) at the same height as the circuit element.

FIGS. 4 to 8 are cross-sectional views of a method of manufacturing a touch screen panel according to an embodiment of the subject invention.

Although trace lines formed on a glass substrate, and ports are not shown in FIGS. 4 to 8, the trace lines and the ports can actually be patterned in advance on the glass substrate. For example, the trace lines and the ports can be patterned in advance with ITO or a metal, though embodiments are not limited thereto.

Referring FIG. 4, a thin film 110 can be coated on a substrate 10. The thin film 110 can be, for example, ITO, though embodiments are not limited thereto. The substrate 100 can be, for example, a glass substrate, though embodiments are not limited thereto. Referring to FIG. 5, the driving lines 111 and the sensing patterns 112 to be connected to the sensing lines 130 later can be formed by patterning the thin film 110. Here, the sensing patterns 112 can be formed at positions where the sensing patterns 112 are to be connected to the trace lines 160 patterned in advance.

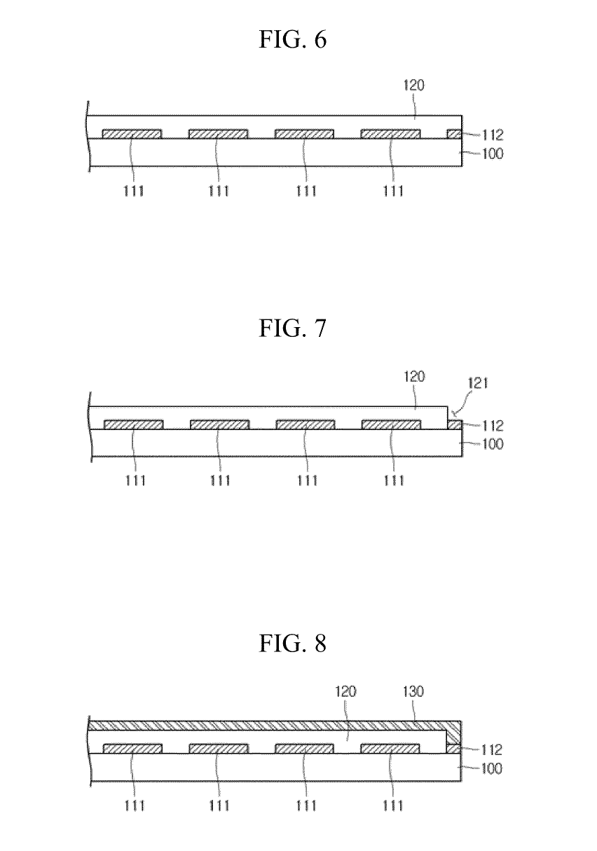

Referring to FIG. 6, the dielectric 120 can be formed on the driving lines 111, the sensing patterns 112, and the substrate 100.

Referring FIG. 7, a via hole 121 can be formed in the dielectric 120 is performed. The via hole 121 can be formed at a position where a top surface of the sensing patterns 112 is exposed.

Referring to FIG. 8, the sensing lines 130 can be formed by depositing a thin film on the dielectric 120 having the via hole 121 formed therein. The thin film deposited for the sensing lines can be, for example, ITO or a metal, though embodiments are not limited thereto. In an embodiment, the via hole 121 can be filled with ITO through an ITO thin film depositing process to form the sensing lines 130. After deposition on the dielectric 120 having the via hole 121, the sensing patterns 112 and the sensing lines 130 can be connected through the via hole 121. That is, the sensing lines 130 can also be formed on a top portion and side walls of the dielectric 120.

Although not shown in the drawings, a transparent layer (e.g., window glass) can be formed on the sensing lines 130. This can be done, for example, by using an optical clear adhesive (OCA), though embodiments are not limited thereto. The transparent layer, such as window glass, is a layer which a user touches, and plays a role of protecting components inside the touch screen panel from the outside.

In touch screen panel according to embodiments of the subject invention, trace lines formed to receive electric signals from the driving lines and sensing lines can intersect with each other, and wires can be formed on the same horizontal plane. Accordingly disconnections of wires can be markedly reduced.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

What is claimed is:

1. A touch screen panel, comprising:
a substrate;
a plurality of driving lines on the substrate;
a plurality of sensing patterns on the substrate;
a dielectric formed on the substrate and the driving lines;
a plurality of sensing lines on the dielectric and arranged in a perpendicular direction to the driving lines,; and
a plurality of trace lines, wherein each driving line of the plurality of driving lines is electrically connected to a trace line and each sensing line of the plurality of sensing lines is electrically connected to a trace line,
wherein each sensing line is electrically connected to a sensing pattern of the plurality of sensing patterns.

2. The touch screen panel according to claim 1, wherein the driving lines, the sensing patterns, and the trace lines are all formed at a same height from the substrate, such that upper surfaces of the driving lines, the sensing patterns, and the trace lines are all horizontally aligned with each other with respect to the substrate.

3. The touch screen panel according to claim 1, further comprising a via hole in the dielectric,
wherein the sensing lines are connected to the sensing patterns through the via hole.

4. The touch screen panel according to claim 1, wherein the driving lines, the sensing patterns, and the sensing lines are all formed of an indium tin oxide (ITO) thin film.

5. The touch screen panel according to claim 1, wherein the substrate is a transparent substrate.

6. The touch screen panel according to claim 1, wherein the substrate is a glass substrate.

7. The touch screen panel according to claim 1, further comprising a plurality of ports, wherein each trace line is connected to a port of the plurality of ports.

8. The touch screen panel according to claim 7, wherein the plurality of ports are connected to a circuit element configured to measure capacitance transferred from the driving lines.

9. The touch screen panel according to claim 8, wherein the circuit element configured to measure capacitance transferred from the driving lines is a flexible printed circuit board.

10. The touch screen panel according to claim 1, wherein each sensing line is in direct physical contact with a sensing pattern of the plurality of sensing patterns.

11. A method of manufacturing a touch screen, the method comprising:
forming a thin film on a substrate;
forming a plurality of sensing patterns and a plurality of driving lines by patterning the thin film;
forming a dielectric over the driving lines and the substrate; and
forming a plurality of sensing lines on the dielectric and arranged in a perpendicular direction to the driving lines,
wherein each sensing line is electrically connected to a sensing pattern of the plurality of sensing patterns.

12. The method according to claim 11, wherein forming the dielectric comprises forming the dielectric over the driving lines, the substrate, and the sensing patterns, and
wherein the method further comprises, before forming the plurality of sensing lines:
forming a via hole in the dielectric to expose a top surface of the sensing patterns; and
depositing a conductive material for the sensing lines on the dielectric and in the via hole, such that sensing lines are electrically connected to the sensing patterns through the via hole.

13. The method according to claim 11, further comprising adhering a window glass on the sensing lines by using an optical clear adhesive (OCA).

14. The method according to claim 11, wherein the driving lines and the sensing patterns are all formed at a same height from the substrate, such that upper surfaces of the driving lines and the sensing patterns are all horizontally aligned with each other with respect to the substrate.

15. The method according to claim 11, further comprising forming a plurality of trace lines, wherein each driving line of the plurality of driving lines is electrically connected to a trace line and each sensing line of the plurality of sensing lines is electrically connected to a trace line,
wherein the driving lines, the sensing patterns, and the trace lines are all formed at a same height from the substrate, such that upper surfaces of the driving lines, the sensing patterns, and the trace lines are all horizontally aligned with each other with respect to the substrate.

16. The method according to claim 11, wherein the thin film is an indium tin oxide (ITO) thin film.

17. The method according to claim 11, wherein the substrate is a transparent substrate.

18. The method according to claim 11, wherein each sensing line is in direct physical contact with a sensing pattern of the plurality of sensing patterns.

19. The method according to claim 12, wherein each sensing line is in direct physical contact with a sensing pattern of the plurality of sensing patterns.
